(19) United States
(12) Patent Application Publication
(10) Pub. No.: US 2018/0366477 A1
(43) Pub. Date: Dec. 20, 2018

(54) FERROELECTRIC TUNNEL JUNCTION UNIT, A MANUFACTURING METHOD OF A FERROELECTRIC FILM THEREOF, A MEMORY ELEMENT, AND A METHOD OF READING AND WRITING THE MEMORY

(71) Applicant: NUSTORAGE TECHNOLOGY CO., LTD., APIA (WS)

(72) Inventor: FU-CHOU LIU, HSIN-CHU COUNTY (TW)

(21) Appl. No.: 15/953,363

(22) Filed: Apr. 13, 2018

(30) Foreign Application Priority Data
Jun. 14, 2017 (CN) 201710447991.1

(51) Int. Cl. H01L 27/11507; H01L 49/02; H01L 21/02; H01L 21/3105; H01L 23/528; G11C 11/22

(52) U.S. Cl. CPC H01L 27/11507; H01L 28/60; H01L 21/022; H01L 21/3105; H01L 23/528; G11C 11/221; G11C 11/2273; H01L 21/02181; H01L 21/02189; H01L 21/02194; G11C 11/2275

(57) ABSTRACT

A ferroelectric tunnel junction unit, a manufacturing method of a ferroelectric film thereof, a memory element, and a method of reading and writing the memory element are disclosed. The ferroelectric tunnel junction unit includes: a first electrode, a second electrode and a ferroelectric film sandwiched between the first and the second electrodes. The ferroelectric film includes at least a base substance and a number of dopants, the base substance including two oxides. Each oxide is at least one of an alkaline earth metal oxide and a transition metal oxide. The dopants include aluminum, silicon, titanium, tantalum, nitrogen, lanthanum, tantalum nitride, titanium nitride, or any combination thereof. By doping different dopants into the base substance of the ferroelectric film and adjusting the doping concentration of the dopants, a coercive electric field of the ferroelectric film may be tuned.

### FIELD OF THE INVENTION

The present disclosure relates to a semiconductor nonvolatile memory element storing data through adjusting resistance therein and a manufacturing method of a part of the structure of the semiconductor nonvolatile memory element, and especially to a manufacturing method of a ferroelectric film, a ferroelectric tunnel junction unit having the ferroelectric film, a memory element, and a method of reading and writing the memory element.

### BACKGROUND OF THE INVENTION

A ferroelectric tunnel junction (FTJ) structure often includes a top electrode, a bottom electrode and a ferroelectric material layer sandwiched between the top and bottom electrodes. The directions of electric dipole moments in the ferroelectric material layer change with externally applied electric fields, thus polarizing the ferroelectric material layer.

When a read voltage is applied to the FTJ structure, the polarization direction of the ferroelectric material layer varies accordingly and influences a barrier height formed at a junction between the ferroelectric material layer and the top electrode, as well as a barrier height formed at a junction between the ferroelectric material layer and the bottom electrode. The barrier heights respectively formed at the two junctions may influence the value of a tunneling current and thus alter the resistance of the ferroelectric material layer. Specifically, when a large enough positive voltage is applied to the top electrode of the FTJ structure, the polarization direction of the ferroelectric material layer is forced to point from the top electrode towards the bottom electrode. At this time, the barrier height formed at the junction between the ferroelectric material layer and the top electrode is lower, while the barrier height formed at the junction between the ferroelectric material layer and the bottom electrode is higher.

Under the above circumstance, when a positive read voltage that is low enough to avoid disturbing the polarization direction of the ferroelectric material layer is applied to the top electrode, it would be hard for electrons to tunnel across the barrier between the bottom electrode and the ferroelectric material layer to reach the top electrode, resulting in measurements of a smaller tunneling current and higher resistance.

When a large enough negative voltage is applied to the top electrode of the FTJ structure, the polarization direction of the ferroelectric material layer is forced to point from the bottom electrode towards the top electrode. The barrier height formed at the junction between the ferroelectric material layer and the top electrode is higher, while the barrier height formed at the junction between the ferroelectric material layer and the bottom electrode is lower. In this condition, when the read voltage is applied to the FTJ structure, it would be easy for electrons to tunnel from the bottom electrode to the top electrode, resulting in measurements of a larger tunneling current and lower resistance.

The minimum applied electric field required to reverse the polarization direction of the ferroelectric material layer is called a coercive electric field. The conventional ferroelectric material layer is usually made of a material having a perovskite structure, such as BiFeO₃ or BaTiO₃, etc. However, the coercive electric field of the material having the perovskite structure usually cannot be adjusted according to practical requirements and thereby limits the application of the FTJ structure.

Furthermore, these materials have to be used in cooperation with the bottom electrode made of La_{0.67}Sr_{0.33}MnO₃ or Ca_{0.96}Ce_{0.04}MnO₃ and the top electrode made of cobalt. However, due to the complexity of the materials of the aforementioned ferroelectric material layer and the bottom electrode, the fabrication processes of the FTJ structure cannot be easily integrated into the conventional semiconductor processes.

### SUMMARY OF THE INVENTION

The object of the present disclosure is to provide a ferroelectric film of a ferroelectric tunnel junction unit with a coercive electric field being adjustable according to different requirements. Furthermore, the manufacturing method of the ferroelectric film of the ferroelectric tunnel junction unit can be integrated into current semiconductor processes.

In order to achieve the aforementioned objects, according to an embodiment of the disclosure, a ferroelectric tunnel junction (hereafter “FTJ”) unit is provided. The FTJ unit includes: a first electrode, a second electrode, and a ferroelectric film sandwiched between the first electrode and the second electrode. The ferroelectric film includes at least a base substance and a number of dopants. The base substance includes two oxides, each oxide is at least one of an alkaline earth metal oxide and a transition metal oxide, and the dopants include aluminum, silicon, titanium, tantalum, nitrogen, lanthanum, tantalum nitride, titanium nitride, or any combination thereof.

According to another embodiment of the disclosure, a manufacturing method of a ferroelectric film is provided. First, a laminate body including a first base substance stack structure and at least one dopant material structure is formed. The first base substance stack structure includes at least one oxide. The oxide is at least one of an alkaline earth metal oxide and a transition metal oxide. The dopant material structure includes a number of dopants, and the dopants include aluminum, silicon, titanium, tantalum, nitrogen, lanthanum, tantalum nitride, titanium nitride, or any combination thereof. A heating process is then performed on the laminate body so that atoms in the first base substance stack structure interdiffuse with the dopants in the dopant material structure to form the ferroelectric film.

According to another embodiment of the disclosure, a memory element is provided. The memory element includes a plurality of bit lines extending along a first direction, a plurality of common-source lines extending along the first direction, a plurality of word lines extending along a second direction, a plurality of transistors, and a plurality of FTJ units. The common-source lines and the bit lines are alternately arranged and the word lines respectively intersect with the common-source lines and the bit lines to define a plurality of cell regions. The transistors are respectively arranged in the cell regions, and each of the transistors includes a source electrode, a drain electrode and a gate electrode. The drain electrode is electrically connected to the corresponding bit line, and the gate electrode is electrically connected to the corresponding word line. The FTJ units are respectively arranged in the cell regions and respectively electrically connected to the transistors. Each of the FTJ units includes a first electrode electrically connected to the source electrode, a second electrode electrically connected to the corresponding common-source line, and a ferroelectric film sandwiched between the first electrode and the second electrode. The ferroelectric film includes a base substance and a number of dopants. The base substance includes two oxides, and each oxide is at least one of an alkaline earth metal oxide and a transition metal oxide. The dopants include aluminum, silicon, titanium, tantalum, nitrogen, lanthanum, tantalum nitride, titanium nitride, or any combination thereof.

According to another embodiment of the disclosure, a method of writing and reading abovementioned memory element is provided. The method includes the steps of applying a reference voltage to each of the common-source lines; selecting a first cell region from the cell regions, in which a first transistor unit and a first FTJ unit electrically connected thereto are arranged in the first cell region; applying a predetermined voltage to the corresponding word line of the first cell region so as to turn on the first transistor unit; applying a first operation voltage to a corresponding first bit line of the first cell region so as to create a first voltage difference between the first operation voltage and the reference voltage; and determining whether the first FTJ unit is in a written state or in an unwritten state according to the first voltage difference and a threshold voltage of the first FTJ unit.

To sum up, in the embodiment of the present disclosure, by doping different types of dopants into the base substance of the ferroelectric film and adjusting the doping concentration of dopants, the coercive electric field of the ferroelectric film can be adjusted, thereby expanding the range of application of the FTJ unit. In addition, the manufacturing method of the FTJ unit can be easily integrated into current semiconductor processes.

To further understand the techniques, means and effects of the present disclosure, the following detailed descriptions and appended drawings are hereby referred to, such that, and through which, the purposes, features and aspects of the present disclosure can be thoroughly and concretely appreciated. However, the appended drawings are provided solely for reference and illustration, without any intention to limit the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 shows a flowchart of a manufacturing method of a ferroelectric film according to an embodiment of the present disclosure.

FIG. 2 shows a fragmentary sectional view of the ferroelectric film in step S100 of FIG. 1 according to an embodiment of the present disclosure.

FIG. 3 shows a fragmentary sectional view of the ferroelectric film in step S100 of FIG. 1 according to another embodiment of the present disclosure.

FIG. 4 shows a fragmentary sectional view of a FTJ unit according to an embodiment of the present disclosure.

FIG. 5 shows a schematic current-voltage diagram illustrating the current-voltage characteristics of the FTJ units according to different embodiments of the present disclosure.

FIG. 6 shows a fragmentary equivalent circuit diagram of a memory element according to an embodiment of the present disclosure.

FIG. 7 shows a fragmentary sectional view of the memory element according to an embodiment of the present disclosure.

FIG. 8 shows a flowchart of a method of writing and reading the memory element according to an embodiment of the present disclosure.

FIG. 9 shows an equivalent circuit diagram of the memory element when data is written to the memory element according to an embodiment of the present disclosure.

FIG. 10 shows an equivalent circuit diagram of the memory element when data is read from the memory element according to an embodiment of the present disclosure.

FIG. 11A shows a flowchart of a first part of the method of writing and reading the memory element according to another embodiment of the present disclosure.

FIG. 11B shows a flowchart of a second part of the method of writing and reading the memory element according to another embodiment of the present disclosure.

FIG. 12 shows an equivalent circuit diagram of the memory element when data is written to the memory element according to another embodiment of the present disclosure.

FIG. 13 shows an equivalent circuit diagram of the memory element when data is read from the memory element according to another embodiment of the present disclosure.

### DETAILED DESCRIPTION OF THE PREFERRED EMBODIMENTS

Embodiments of a FTJ unit, a manufacturing method of a ferroelectric film thereof, a memory element, and a method of reading and writing the memory element according to the present disclosure are described herein. Other advantages and objectives of the present disclosure can be easily understood by one skilled in the art from the disclosure. The present disclosure can be applied in different embodiments. Various modifications and variations can be made to various details in the description for different applications without departing from the scope of the present disclosure. The drawings of the present disclosure are provided only for simple illustrations, but are not drawn to scale and do not reflect the actual relative dimensions. The following embodiments are provided to describe in detail the concept of the present disclosure, and are not intended to limit the scope thereof in any way.

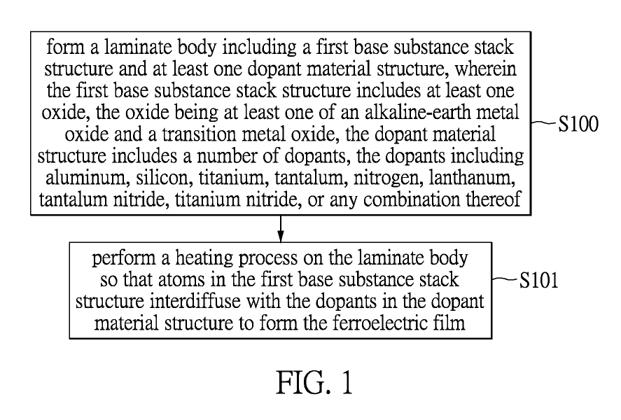

Referring to FIG. 1, FIG. 1 shows a flowchart of a manufacturing method of a ferroelectric film according to an embodiment of the present disclosure. The ferroelectric film fabricated by the method provided in the embodiment can be applied in a FTJ (FTJ) element, and the type and concentration of dopants in the ferroelectric film may be varied to adjust the coercive electric field of the ferroelectric film.

In step S100, a laminate body is formed, the laminate body including a first base substance stack structure and at least one dopant material structure. The first base substance stack structure includes at least one oxide, the oxide being at least one of an alkaline earth metal oxide and a transition metal oxide. The dopant material structure includes a number of dopants, the dopants including aluminum, silicon, titanium, tantalum, nitrogen, lanthanum, tantalum nitride, titanium nitride or any combination thereof.

In the present embodiment, the laminate body further includes a second base substance stack structure, and the dopant material structure is sandwiched between the first base substance stack structure and the second base substance stack structure. Furthermore, the laminate body can be formed by atomic layer deposition (ALD).

Next, in step S101, a heating process is performed on the laminate body so that the atoms in the first base substance stack structure interdiffuse with the dopants in the dopant material structure to form the ferroelectric film. The following example further describes the manufacturing method of the ferroelectric film according to the embodiment of the present disclosure embodiment.

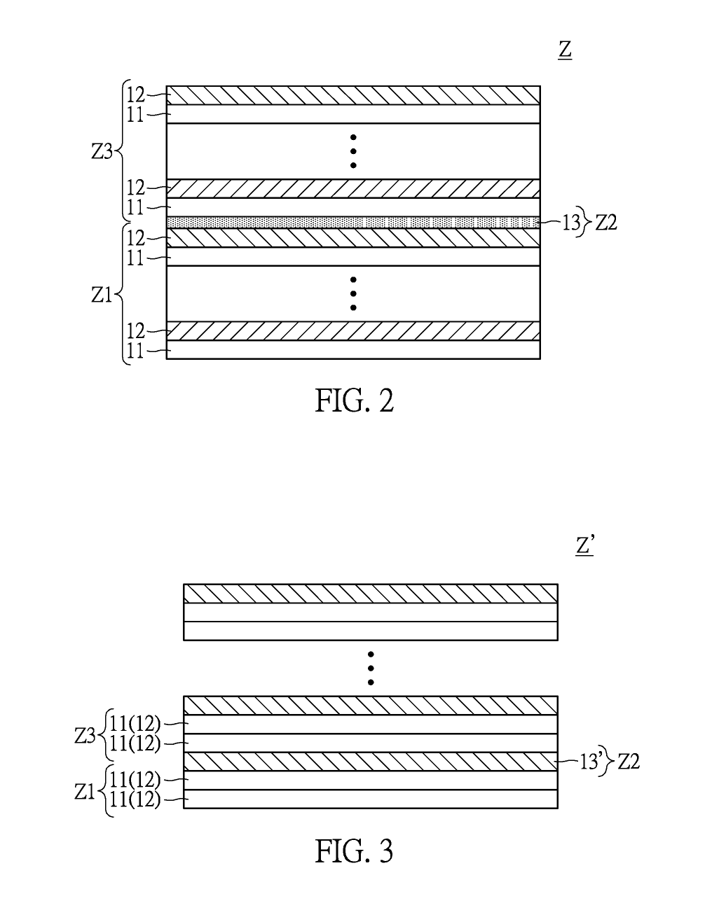

Referring to FIG. 2, a fragmentary sectional view of the ferroelectric film in step S100 of FIG. 1 according to an embodiment of the present disclosure is shown. The laminate body Z of the present embodiment includes a first base substance stack structure Z1, a dopant material structure Z2 and a second base substance stack structure Z3. The laminate body Z can be formed on a first electrode (not shown) or a second electrode (not shown).

In the present embodiment, the first base substance stack structure Z1 includes a first oxide layer 11 and a second oxide layer 12 directly connected to the first oxide layer 11. Each of the first oxide layer 11 and the second oxide layer 12 has at least one oxide that is at least one of the alkaline earth metal oxide and the transition metal oxide. The alkaline earth metal oxide is such as calcium oxide, strontium oxide, barium oxide and the like, and the transition metal oxide is such as hafnium oxide, zirconium oxide, yttrium oxide, gadolinium oxide and the like.

In one embodiment of the present disclosure, the first oxide layer 11 is made of hafnium oxide, and the second oxide layer 12 is made of zirconium oxide. However, the materials of the first oxide layer 11 and the second oxide layer 12 can be selected according to practical requirements as long as the laminate body Z can form a homogeneous phase after being subjected to a heating process.

In addition, in the present embodiment, a plurality of first oxide layers 11 and a plurality of the second oxide layers 12 are stacked alternately to form the first base substance stack structure Z1. As shown in the embodiment illustrated in FIG. 2, the process for stacking the first oxide layers 11 and second oxide layers 12 includes repeating the steps of forming the first oxide layer 11, forming the second oxide layer 12 on the first oxide layer 11, and then forming another first oxide layer 11 on the second oxide layer 12 in a cyclical manner until a predetermined number of layers is reached. In another embodiment (such as the embodiment shown in FIG. 3), each cycle may include the step of forming two (or more) of the first oxide layers 11 that are directly connected to each other, and followed by the step of forming two (or more) of the second oxide layers 12 that are directly connected to each other.

The dopant material structure Z2 includes a number of dopants, and the dopants include aluminum, silicon, titanium, tantalum, nitrogen, lanthanum, tantalum nitride, titanium nitride or any combination thereof. In one embodiment, the dopants include silicon oxide, aluminum oxide, titanium nitride, tantalum nitride or any combination thereof. In the embodiment shown in FIG. 2, the dopant material structure Z2 is a doped layer 13 containing the dopants. For example, the doped layer 13 may be a silicon oxide layer, aluminum oxide layer, titanium nitride layer or tantalum nitride layer, or may be a layer including different materials.

The second base substance stack structure Z3 may have a similar structure to that of the first base substance stack structure Z1, that is, the second base substance stack structure Z3 may include a plurality of the first oxide layers 11 and a plurality of the second oxide layers 12 that are stacked alternately. After the second base substance stack structure Z3 is formed, the steps of forming the dopant material structure Z2, forming the first base substance stack structure Z1 and forming the second base substance stack structure Z3 are then sequentially and repeatedly performed until the laminate body Z reaches a predetermined thickness. The thickness of the laminate body Z may range between 1 nm and 20 nm. If the ferroelectric film is applied in the FTJ unit, the thickness of the laminate body Z may range between 1 nm and 7 nm.

It should be noted that, in the present embodiment, the first oxide layers 11, the second oxide layers 12 and the dopant material structure Z2 can be formed by atomic layer deposition (ALD).

For example, when the first oxide layer 11 is hafnium oxide, the second oxide layer 12 is zirconium oxide and the dopant material structure Z2 is silicon oxide, the precursor employed in the growth of the first oxide layer 11 may be tetrakis(ethylmethylamino)hafnium (TEMAH), tetrakis(dimethylamino)hafnium (TDMAH), or hafnium tetrachloride (HfCl₄). The oxidizer may be ozone (O₃) or water (H₂O).

The precursor employed in the growth of the second oxide layer 12 may be tetrakis(ethylmethylamino)zirconium (TEMAZ), tetrakis(dimethylamino)zirconium (TDMAZ), or zirconium tetrachloride (ZrCl₄).

When the dopant material structure Z2 is a silicon oxide layer, the precursor may be tetrakis(dimethylamino)silane (4DMAS), tris(dimethylamino)silane (3DMAS), or SiCl₄. When the dopant material structure Z2 is aluminum oxide, the precursor may be trimethyl aluminum or aluminum trichloride (AlCl₃). Furthermore, in the atomic layer deposition process, the deposition temperature ranges between about 150° C. and 400° C.

It should be noted that the percentage of each oxide in the base substance can be controlled by adjusting the number of layers of the first oxide layer 11 and the number of layers of second oxide layer 12, and the number of the layers of the dopant material structure Z2 may be adjusted to control the doping concentration of the dopants.

For example, after eight pairs of hafnium oxide layer and zirconium oxide layer are formed, a silicon oxide layer (or an aluminum oxide layer) is formed thereon. The material of the ferroelectric film fabricated by repeating the steps above has a general formula of HfₓZr₍₁₋ₓ₎O_{y} doped with silicon (or aluminum), in which x is 0.5, y is 2, and the doping concentration of silicon (or aluminum) is 11%. That is, the ratio between the hafnium oxide and zirconium oxide, and the doping concentration of the silicon (or aluminum) may be adjusted by controlling the number of the stacked layers.

In one embodiment of the present disclosure, the general formula of the base substance of the ferroelectric film is HfₓZr₍₁₋ₓ₎O_{y}, in which x ranges between 0.25 and 0.75, preferably between 0.4 and 0.6, and y ranges between 1.8 and 2.2, preferably between 1.9 and 2.1. The doping concentration of silicon or aluminum in the base substance ranges between 1% and 5%.

In another embodiment of the present disclosure, the dopant material structure Z2 may also be a tantalum nitride layer or a titanium nitride layer. The precursor employed in the growth of the titanium nitride layer during the atomic layer deposition may include titanium tetrachloride (TiCl₄) or etrakis(diethylamino)titanium (TDEAT). In addition, the precursor further includes ammonia (NH₃). The deposition temperature of the titanium nitride layer ranges between 200° C. and 500° C.

The precursor employed in the growth of the tantalum nitride layer during the atomic layer deposition may include tantalum pentachloride (TaCl₅), tantalum pentafluoride (TaF₅) or tantalum pentabromide (TaBr₅). Furthermore, the precursor further includes ammonia (NH₃), and the deposition temperature of the tantalum nitride layer ranges between 200° C. and 500° C.

In one embodiment, the general formula of the base substance of the ferroelectric film is HfₓZr₍₁₋ₓ₎O_{y}, in which x ranges between 0.25 and 0.75, preferably between 0.4 and 0.6, and y ranges between 1.8 and 2.2, preferably between 1.9 and 2.1. The doping concentration of titanium nitride or tantalum nitride in the base substance ranges between 1% and 10%.

Reference is made to FIG. 3. FIG. 3 shows a fragmentary sectional view of the ferroelectric film in step S100 of FIG. 1 according to another embodiment of the present disclosure. The first base substance stack structure Z1 may include one or a plurality of first oxide layers 11 (or second oxide layers 12). In the present embodiment, the first base substance stack structure Z1 includes two first oxide layers 11. In other embodiments, the first base substance stack structure Z1 may also include only one first oxide layer 11 (or second oxide layer 12).

The second base substance stack structure Z3 can have the same composition and number of stacked layers as the first base substance stack structure Z1. It should be noted that, the compositions and numbers of stacked layers of the first base substance stack structure Z1 and the second base substance stack structure Z3 can be varied according to actual requirements, and are not limited by the embodiments provided herein. For example, the first base substance stack structure Z1 may include more than two first oxide layers 11 so that the amount of the first oxide in the ferroelectric film is greater than that of the second oxide in the ferroelectric film.

As mentioned above, the first oxide layer 11 includes at least one of the alkaline-earth metal oxide and the transition metal oxide. The alkaline-earth metal oxide may be calcium oxide, strontium oxide, barium oxide and the like, and the transition metal oxide may be hafnium oxide, zirconium oxide, yttrium oxide, gadolinium oxide and the like.

In the present embodiment, the dopant material structure Z2 at least includes a doped layer 13′ which contains a transition metal oxide and dopant atoms, and a ratio of the number of the transition metal atoms to a number of dopant atoms ranges between 4 and 9. The dopant atom may be silicon, aluminum and the like, and the transition metal atom may be hafnium, yttrium, gadolinium, zirconium and the like.

In another embodiment, the dopant material structure Z2 may also include two doped layers 13′. Furthermore, the doped layer 13′ and the first oxide layer 11 can respectively contain two different types of transition metal atoms. For example, when the first oxide layer 11 is a zirconium oxide layer, the transition metal atoms contained in the doped layer 13′ can be hafnium atoms, and the dopant atoms can be silicon atoms. To be more specific, the general formula of the material of the doped layer 13′ is HfₓSi_{y}O₂, in which x+y=1, and y<0.25.

When the doped layer 13′ of the present embodiment is formed by the atomic layer deposition, the precursor gas may include tetrakis (ethylmethylamino) silane(TEMA-Si), tetrakis (ethylmethylamino) hafnium(TEMA-Hf) and ozone, and the deposition temperature ranges between about 300° C. and 400° C.

After being subjected to the heating process, the laminate body Z′ shown in FIG. 3 forms the ferroelectric film according to one embodiment of the present disclosure. During the heating process, the annealing temperature ranges between about 400° C. and 600° C. Furthermore, the general formula of the material of the ferroelectric film that is formed by heating the laminate body Z′ shown in FIG. 3 is Hf_{0.8x}Si_{0.2x}Zr₍₁₋ₓ₎O_{y}, in which x ranges between 0.25 and 0.75, preferably between 0.4 and 0.6, and y ranges between 1.8 and 2.2, preferably between 1.9 and 2.1.

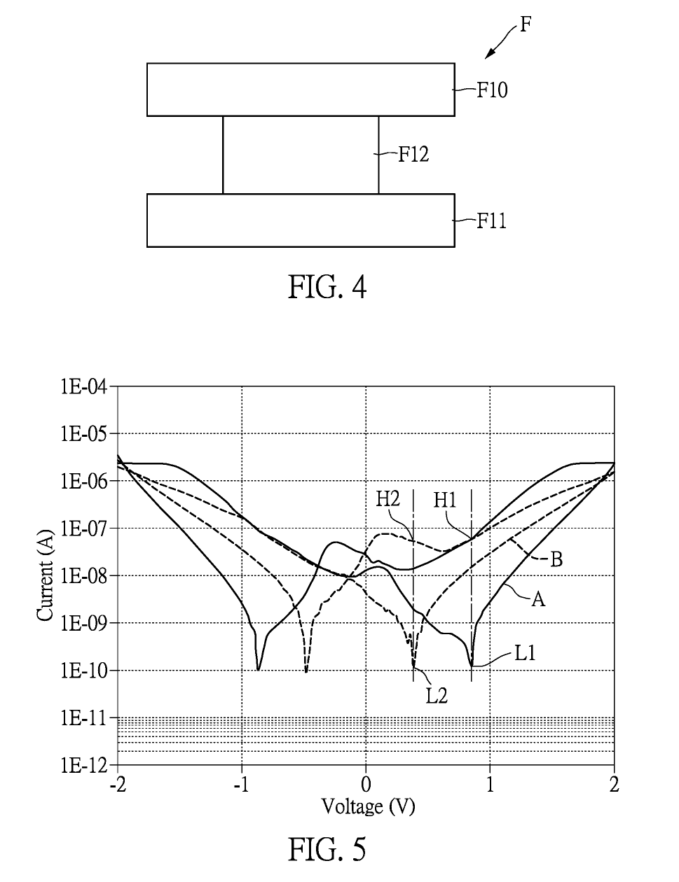

The ferroelectric film formed by the manufacturing method of FIG. 1 can be implemented in a FTJ unit. Referring to FIG. 4, a fragmentary sectional view of a FTJ unit according to an embodiment of the present disclosure is shown.

The FTJ unit F includes a first electrode F10, a second electrode F11 and a ferroelectric film F12 sandwiched between the first electrode F10 and the second electrode F11.

In the present embodiment, the materials of the first electrode F10 and second electrode F11 can be selected from titanium nitride, tantalum nitride and a heavily doped semiconductor. The heavily doped semiconductor is, for example, n-type or p-type silicon. The energy band structures of the first electrode F10 and the second electrode F11 should be in cooperation with that of the ferroelectric film F12 so as to form a Schottky barrier at each of two junctions, one of which is formed between the ferroelectric film F12 and the first electrode F10, and the other one of which is formed between the ferroelectric film F12 and the second electrode F11.

The material of the ferroelectric film F12 at least includes a base substance and a number of dopants, and the base substance includes two oxides, each oxide being at least one of an alkaline-earth metal oxide and a transition metal oxide. The ferroelectric film F12 can be formed by annealing the laminate body Z, Z′ shown in FIG. 2 or in FIG. 3.

In the ferroelectric film F12, the base substance includes hafnium oxide and zirconium oxide, and the dopants include silicon oxide, aluminum oxide or any combination thereof. The dopants include aluminum, silicon, titanium, tantalum, nitrogen, lanthanum, tantalum nitride, titanium nitride or any combination thereof.

For example, the general formula of the base substance is HfₓZr₍₁₋ₓ₎O_{y}, in which x ranges between 0.25 and 0.75, and y ranges between 1.8 and 2.2. The dopants include silicon or aluminum, and the doping concentration of the silicon or aluminum ranges between 1% and 5%. In another embodiment, the dopants include titanium nitride or tantalum nitride, and the doping concentration of the dopants ranges between 1% and 10%.

In yet another embodiment of the present disclosure, the general formula of the base substance is HfₓZr_{(1-1.25x)}O_{y}, in which x ranges between 0.2 and 0.6, and y ranges between 1.8 and 2.2. The dopants include silicon, and the ratio of the number of hafnium atoms to a number of silicon atoms ranges between 4 and 9.

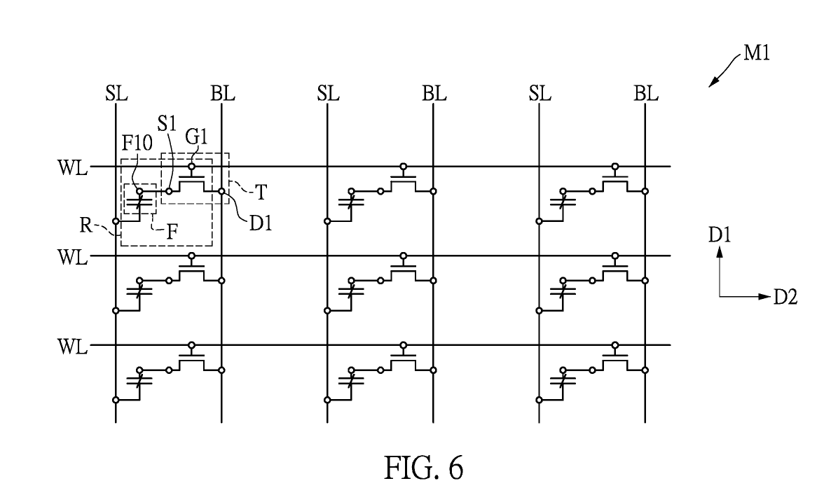

Reference is made to FIG. 5, which shows a schematic current-voltage diagram illustrating the current-voltage characteristics of the FTJ units according to different embodiments of the present disclosure. The curve “A” and the curve “B” respectively represent the current-voltage characteristics of two FTJ units respectively including different ferroelectric films. Specifically, the curve “A” represents current-voltage characteristics of the FTJ unit, of which the ferroelectric film includes an un-doped base substance (without the dopants). The curve “B” represents current-voltage characteristics of the other FTJ unit, of which the ferroelectric film includes the base substance and a number of dopants, which in this case includes titanium nitride.

During the current-voltage (I-V) measurement, the current of the FTJ units is measured by gradual sampling within a range starting from a minimum predetermined value (−2V) to a maximum predetermined value (+2V), and then from the maximum predetermined value back to the minimum predetermined value.

As shown in FIG. 5, the minimum current value L1 of the curve A is measured at a voltage value V1, and the minimum current value L2 of the curve B is measured at another voltage value V2 that is less than the voltage value V1.

Since the voltage value (V1, V2) at which the minimum current value is measured corresponds to the intensity of the coercive electric field of the ferroelectric film, compared with the ferroelectric film including the un-doped base substance, the coercive electric field of the ferroelectric film including the base substance doped with titanium nitride is relatively low. That is to say, the coercive electric field of the ferroelectric film can be adjusted by the use of the dopants. In another embodiment, the coercive electric field of the ferroelectric film can be adjusted by varying the type and the doping concentration of dopants. Therefore, the type and doping concentration of the dopants may be adjusted so that the characteristics of the ferroelectric film can satisfy the requirements of particular implementations.

Furthermore, it should be noted that two points H1, L1 of the curve “A” corresponding to the voltage value V1 respectively represent the measured currents of the ferroelectric film including the un-doped base substance in the low resistance state and in the high resistance state. The larger the difference between the two measured currents H1, L1, the easier the state of the FTJ unit is determined.

Accordingly, when the FTJ unit is applied in the memory element, the read voltage and write voltage of the memory element can be set according to the voltage value V1, with the write voltage usually being 2 to 3 times greater than the read voltage. Therefore, the greater the voltage value V1 corresponding to the minimum current value L1, the higher the power consumption of the memory element.

Since the voltage value V2 corresponding to the minimum current value L2 of the curve “B” is less than the voltage value V1 corresponding to the minimum current value L1 of the curve “A”, the read voltage and the write voltage required for operation of the memory element having the ferroelectric film are relatively lower, thereby reducing the power consumption of the memory element.

However, in another application, the type and doping concentration of dopants in the ferroelectric film can also be varied so that the coercive electric field of the ferroelectric film with the dopants is higher than that of the ferroelectric film without the dopants. For example, when aluminum oxide or silicon oxide of lower electrical conductivity is used as the dopants, compared with the ferroelectric film without the dopants, the coercive electric field of the ferroelectric film with dopants is higher. That is to say, the minimum current value of the I-V curve of the FTJ unit including the ferroelectric film doped with aluminum oxide or silicon oxide corresponds to higher voltage.

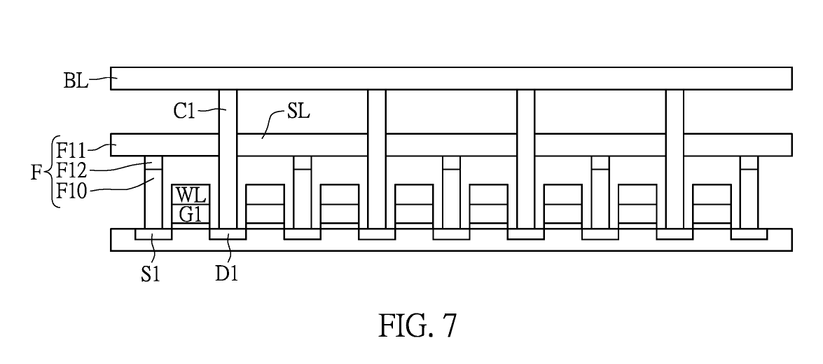

Referring to FIG. 6 and FIG. 7, FIG. 6 shows a fragmentary equivalent circuit diagram of a memory element according to an embodiment of the present disclosure, and FIG. 7 shows a fragmentary sectional view of the memory element according to an embodiment of the present disclosure.

As shown in FIG. 6, the memory element M1 includes a plurality of bit lines BL, a plurality of common-source lines SL, a plurality of word lines WL, a plurality of transistors T and a plurality of FTJ units F.

The bit lines BL and the common-source lines SL extend along a first direction D1 and are alternately arranged. The word lines WL extend along a second direction D2, such that the word lines WL respectively intersect with the common-source lines SL and the bit lines BL so as to define a plurality of cell regions R.

It should be noted that the word lines WL, the common-source lines SL and the bit lines BL are all electrically connected to a control circuit and a process unit. The process unit controls the voltages respectively applied to each of the word lines WL, the common-source lines SL and the bit lines BL through the control circuit so as to write data in the memory element or read data from the memory element.

The transistors T are respectively arranged in the plurality of cell regions R. Each transistor unit T includes a source electrode S1, a drain electrode D1 and a gate electrode G1. The drain electrode D1 is electrically connected to the corresponding bit line BL, and the gate electrode G1 is electrically connected to the corresponding word line WL.

The transistors T are respectively arranged in the cell regions R. Each of the transistors T includes a source electrode S1, a drain electrode D1, and a gate electrode G1, in which the drain electrode D1 is electrically connected to the corresponding bit line BL, and the gate electrode G1 is electrically connected to the corresponding word line WL.

The FTJ units F are respectively arranged in the cell regions R. The FTJ units F are respectively electrically connected to the transistors T. Each of the FTJ units F can be the FTJ unit F shown in FIG. 4, and have the first electrode F10, the second electrode F11 and the ferroelectric film F12 sandwiched between the first electrode F10 and the second electrode F11. The material of the ferroelectric film F12 has been described above in detail, and will be omitted herein. As shown in FIG. 6, the first electrode F10 is electrically connected to the source electrode S1 of the corresponding transistor T, and the second electrode F11 is electrically connected to the corresponding common-source line SL.

The FTJ unit F has a threshold voltage. If a voltage higher than the threshold voltage is applied to the FTJ unit F, the ferroelectric film F12 of the FTJ unit F will be polarized, which results in variation of the resistance of the ferroelectric film F12. Accordingly, a written state of the FTJ unit F can be determined by measuring the resistance of the ferroelectric film F12.

In actual operation of the memory element M1, a reference voltage provided by the control circuit is applied to each of the common-source lines SL, and the reference voltage should be lower than the threshold voltage of each of the FTJ unit F. In one embodiment of the present disclosure, the reference voltage is ⅓ of the threshold voltage.

Reference is made to FIG. 7. As shown in FIG. 7, the drain electrode D1 of each transistor T can be electrically connected to the corresponding bit line BL via a conductive post C1. Furthermore, the first electrode F10 of the FTJ unit F is in electrical contact with the source electrode S1 of the transistor T, and the second electrode F11 of the FTJ unit F is in electrical contact with the corresponding common-source line SL.

In order to write or read the state of each of the FTJ units F, a voltage is applied to the gate electrode G1 through the corresponding word line WL to turn on the transistor T. Meanwhile, the first electrode F10 electrically connected to the source electrode S1 is held at equal potential with the corresponding bit line BL, and the second electrode F11 is held at equal potential with the common-source line SL. Accordingly, when a voltage difference between the bit line BL and the common-source line SL is greater than the threshold voltage of the FTJ unit F, and the direction of the electric field created between the first electrode F10 and the second electrode F11 is opposite to the polarization direction of the ferroelectric film F12, the polarization direction of the ferroelectric film F12 is driven to be reversed. Based on the above principle, data can be written in or read from the memory element M1. The method of writing and reading the memory element according to the embodiments of the present disclosure will be described in detail in the following.

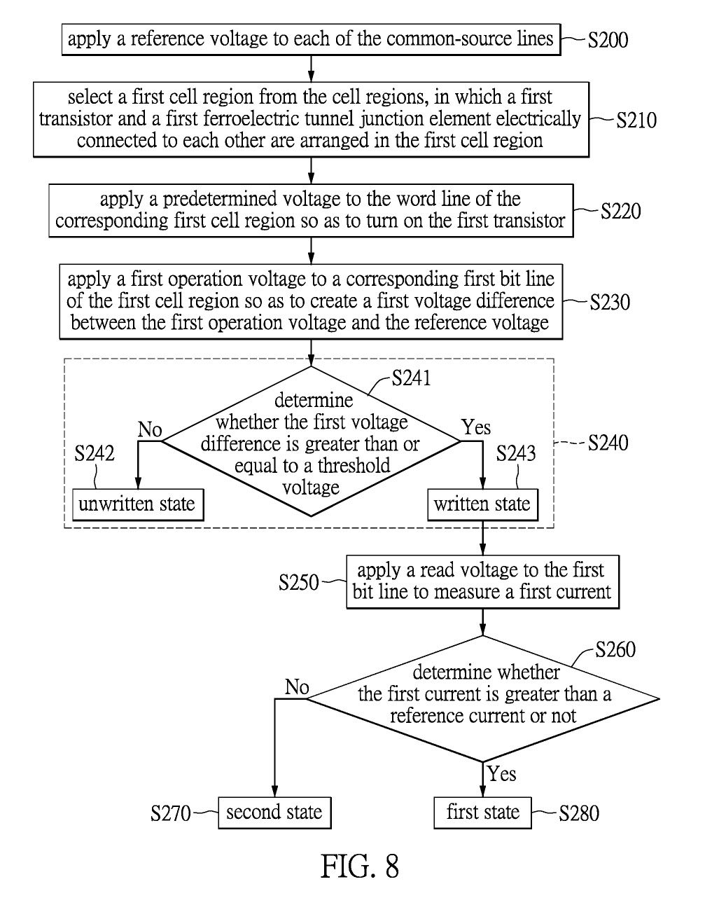

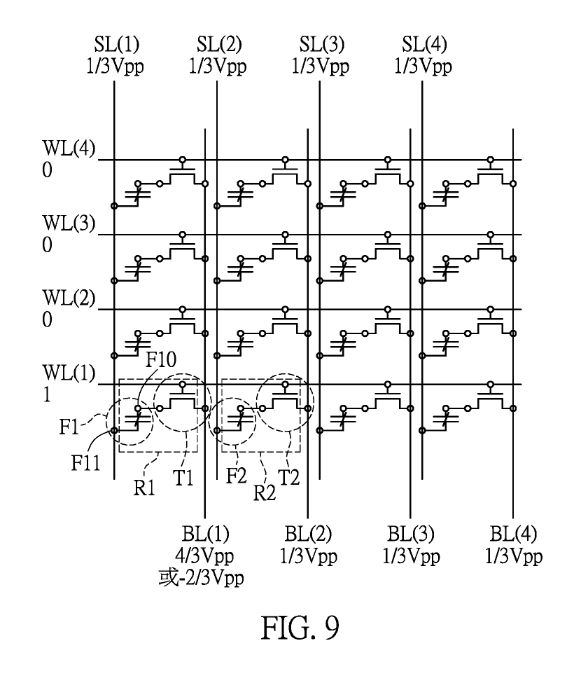

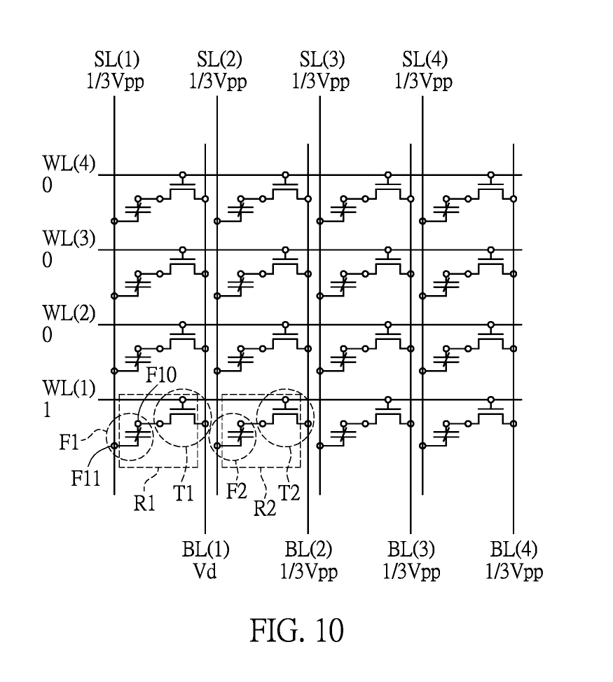

Reference is made to FIG. 8 to FIG. 10. FIG. 8 shows a flowchart of a method of writing and reading the memory element according to an embodiment of the present disclosure. FIG. 9 shows an equivalent circuit diagram of the memory element when data is written to the memory element according to an embodiment of the present disclosure. FIG. 10 shows an equivalent circuit diagram of the memory element when data is read from the memory element according to an embodiment of the present disclosure.

In step S200, a reference voltage is applied to each of the common-source lines. As shown in FIG. 9, the reference voltage is applied to each of the common-source lines SL. In order to prevent the states of the FTJ units F in other un-selected cell regions R from being disturbed during the programming of one of the FTJ units F in a selected cell region R, the reference voltage is not equal to zero or is less than half of the threshold voltage (Vpp) of the FTJ unit F. In an exemplary embodiment of the present disclosure, the reference voltage is ⅓ of the threshold voltage.

Referring to FIG. 8, in step S210, a first cell region of the cell regions is selected, and a first transistor and a first FTJ unit electrically connected to each other are arranged in the first cell region.

As shown in FIG. 9, the first cell region R1 defined by the word line WL(1), the common-source line SL(1), and the bit line BL(1) is selected for description. A first transistor T1 and a first FTJ unit F1 electrically connected to the first transistor T1 are arranged in the first cell region R1.

Referring to FIG. 8, in step S220, a predetermined voltage is applied to the corresponding word line of the first cell region so as to turn on the first transistor T1.

As shown in FIG. 9, a predetermined voltage is applied to the word line WL(1). In this way, the first transistor T1 electrically connected to the word line WL(1) is turned on, such that the first electrode F10 of the first FTJ unit F1 and the bit line BL(1) are set at equal potential.

Referring to FIG. 8, in step S230, a first operation voltage is applied to a corresponding first bit line of the first cell region so as to create a first voltage difference between the first operation voltage and the reference voltage.

As shown in FIG. 9, when the first FTJ unit F1 in the first cell region R1 is programmed, a first operation voltage is applied to the bit line BL(1). In the present embodiment, for the first cell region R1 selected to be programmed, the first operation voltage applied to the first bit line BL is 4/3 of or −⅔ of the threshold voltage (Vpp) (i.e., 4/3Vpp or −⅔Vpp) so that the first FTJ unit F1 is in a written state.

Specifically, when the first operation voltage is −⅔ of the threshold voltage, the first voltage difference, i.e., the voltage difference between the first and second electrodes F10, F11, is equal to the threshold voltage that reverses the polarization direction of the ferroelectric film F12, and the direction of the electric field in the ferroelectric film F12 points from the second electrode F11 to the first electrode F10. Accordingly, the written state of the first FTJ unit F1 is a first state with low resistance.

On the other hand, when the first operation voltage is 4/3 of the threshold voltage, the polarization direction of the ferroelectric film F12 may be changed by the first voltage difference, but the direction of the electric field in the ferroelectric film F12 would point from the first electrode F10 to the second electrode F11. Accordingly, the written state of the first FTJ unit F1 is a second state with high resistance.

Furthermore, the method of writing and reading the memory element according to the embodiments of the present disclosure may further include: selecting a second cell region adjacent to the first cell region, in which a second transistor and a second FTJ unit electrically connected to the second transistor are arranged in the second cell region, and the first transistor and the second transistor are electrically connected to the same word line; and applying a second operation voltage to a second bit line corresponding to the second FTJ unit so as to create a second voltage difference between the second operation voltage and the reference voltage.

Reference is made to FIG. 9. The second cell region R2 is adjacent to the first cell region R1, and defined by the word line WL(1), the bit line BL(2) and the common-source line SL(2).

It should be noted that when the first FTJ unit F1 in the first cell region R1 is written and the second FTJ unit F2 in the second cell region R2 is not yet written, the second operation voltage applied to the bit line BL(2) is ⅓ of the threshold voltage so that the second voltage difference (i.e., the voltage difference between the bit line BL(2) and the common-source line SL(2)) between the first electrode F10 and the second electrode F11 in the second cell region R2 is equal to zero so as to prevent the resistance of the second FTJ unit F2 from being disturbed and avoid the occurrence of a write error.

Reference is made to FIG. 8. In step S240, whether the first FTJ unit is in a written state or an unwritten state is determined according to the first voltage difference (or the second voltage difference) and the threshold voltage of the first FTJ unit (or the threshold voltage of the second FTJ unit).

Specifically, in step S241, whether the first voltage difference is greater than or equal to the threshold voltage is determined. When the first voltage difference is less than the threshold voltage, the method proceeds to step S242: the first FTJ unit is determined to be in the unwritten state. When the first voltage difference is greater than or equal to the threshold voltage, the method proceeds to step S243, that is, the first FTJ unit is determined to be in the written state.

Accordingly, after the first FTJ unit in the first cell region is determined to be in the written state, in step S250, a read voltage is applied to the first bit line to measure a first current.

Reference is made to FIG. 10. When the first FTJ unit F1 is determined to be in the written state, a read voltage Vd is applied to the bit line BL(1). In the present embodiment, a ratio of the read voltage to the threshold voltage ranges between 0.4 and 0.8.

That is to say, during the determination of the written state of the first FTJ unit F1, the absolute value of the voltage difference between the read voltage Vd and the voltage applied to the common-source line SL(1) is less than the threshold voltage of the first FTJ unit F1 to prevent the written state of the FTJ unit in another cell region from being disturbed. After the read voltage is applied to the bit line BL(1), the first current through the first FTJ unit F1 can further be measured.

In addition, before the written state of the second FTJ unit F2 is determined, the second operation voltage applied to the bit line BL(2) corresponding to the second cell region R2 is still ⅓ of the threshold voltage. Therefore, the second voltage difference between the second operation voltage and the reference voltage applied to the common-source line SL(2) is equal to zero, so that the written state of the second FTJ unit F2 would not be disturbed.

Next, reference is made to FIG. 8. In step S260, whether the first current is greater than a reference current or not is determined. The reference current may be set to be the average of the measured current through the first FTJ unit F1 with high resistance and the measured current through the first FTJ unit F1 with low resistance.

Accordingly, when the first current is greater than the reference current, the method proceeds to step S280, that is, the written state of the first FTJ unit is determined to be the first state with low resistance. If the first current is less than the reference current, the method proceeds to step S270 and the written state of the first FTJ unit is determined to be the second state with high resistance. The first state and second state may be respectively defined as “1” and “0”, and vice versa.

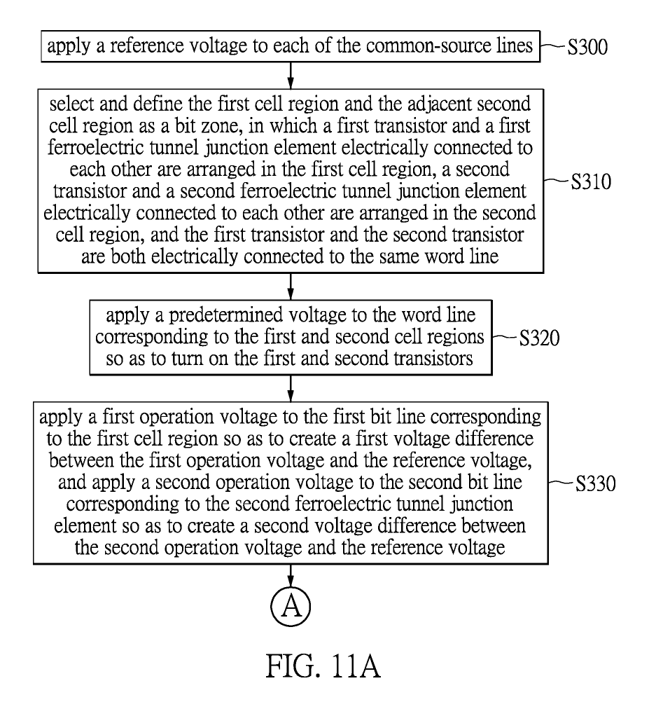

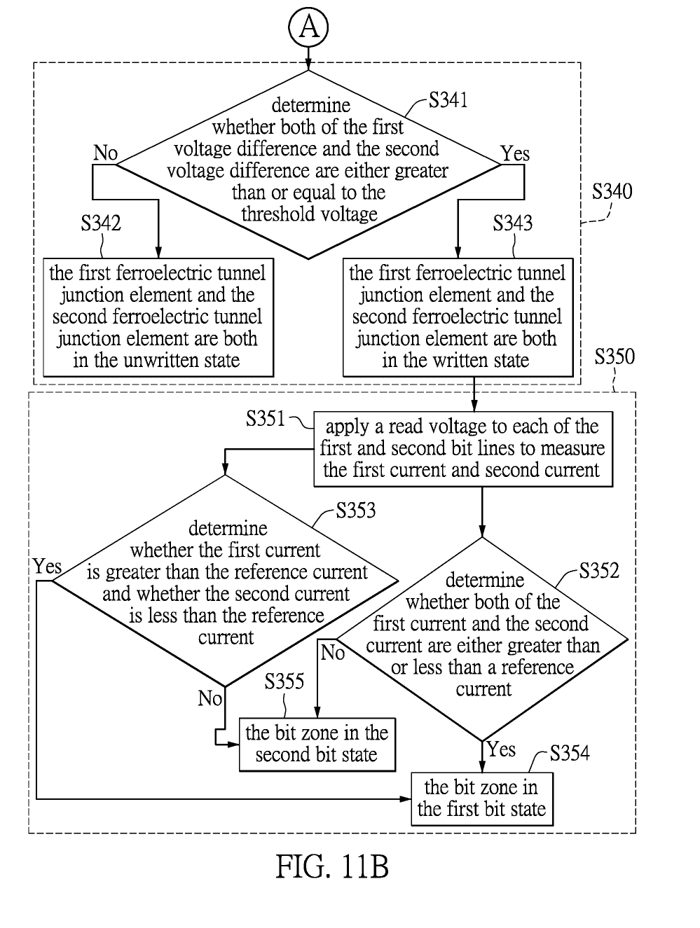

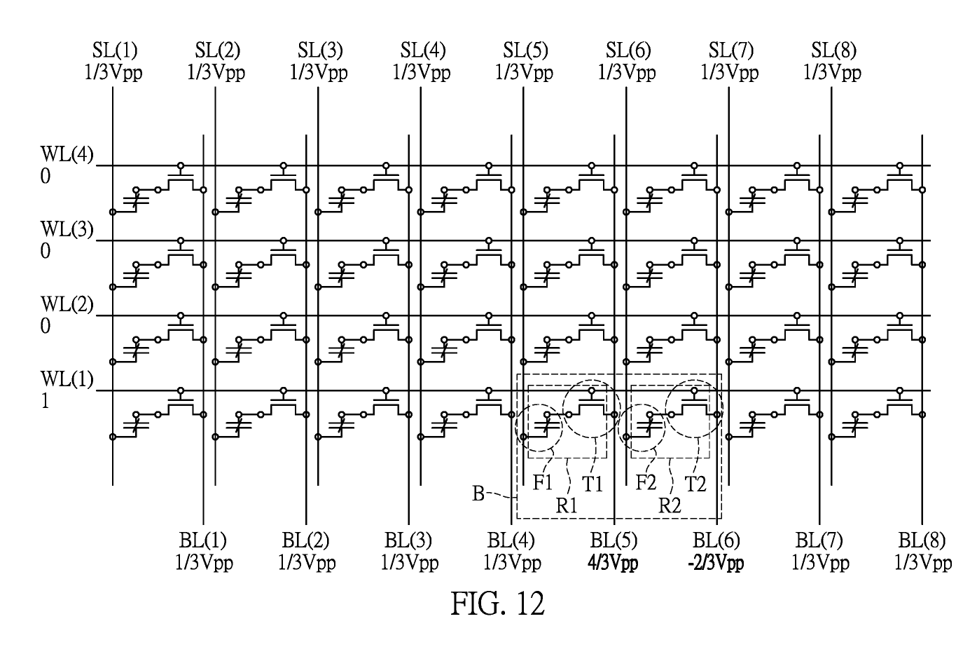

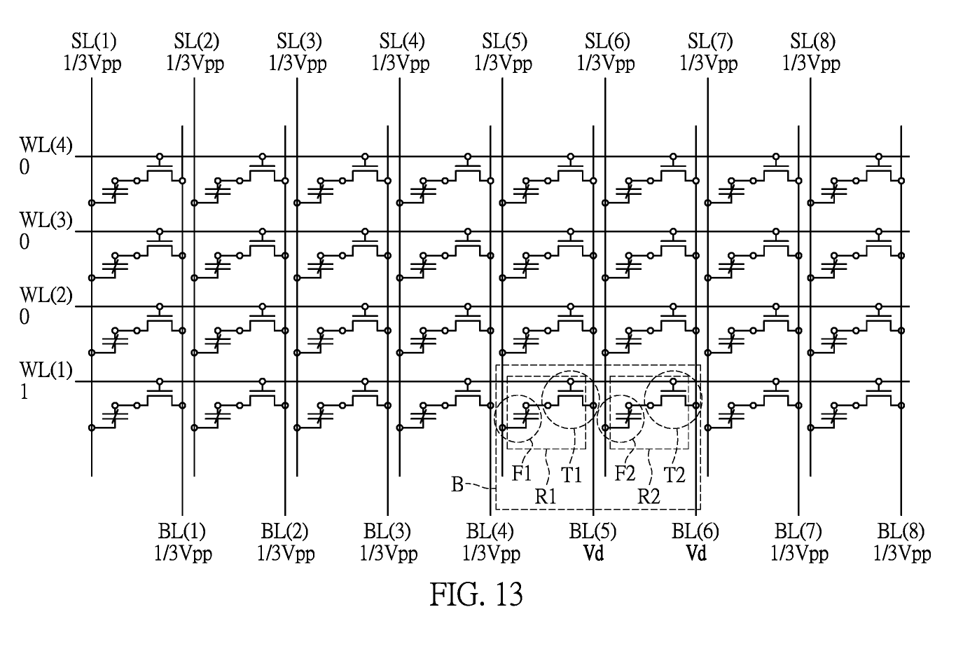

Reference is made to FIG. 11A to FIG. 13. FIG. 11A shows a flowchart of a first part of the method of writing and reading the memory element according to another embodiment of the present disclosure, and FIG. 11B shows a flowchart of a second part of the method of writing and reading the memory element according to another embodiment of the present disclosure. FIGS. 12 and 13 respectively show equivalent circuit diagrams of the memory element when data is written to and read from the memory element according to another embodiment of the present disclosure.

It should be noted that the FTJ units arranged in two cell regions spaced apart from each other would have different characteristics due to the fabrication limitations thereof. For example, even though the ferroelectric films of the FTJ units are formed in the same deposition process, the ferroelectric films of the FTJ units respectively arranged in different cell regions may respectively have different thicknesses since the deposition positions of the ferroelectric films are different. As such, for two FTJ units respectively with high resistance and low resistance that are arranged apart from each other, it is likely that the current measured would be substantially the same. If the same reference current is used when the written state of the FTJ unit is read, the written state of the FTJ unit may be mis-determined.

Accordingly, in the method of writing and reading the memory element according to another embodiment of the present disclosure, two adjacent cell regions are defined as a bit zone to be written and read. In this way, the errors or difficulty in determination due to large differences in the characteristics of the FTJ units that are arranged at different locations during the fabrication process can be reduced.

As shown in FIG. 11A, in step S300, a reference voltage is applied to each of the common-source lines, and in step S310, the first cell regions and the adjacent second cell region of the cell regions are defined as a bit zone. A first transistor and a first FTJ unit electrically connected to each other are arranged in the first cell region. A second transistor and a second FTJ unit electrically connected to each other are arranged in the second cell region, and the first transistor and the second transistor are both electrically connected to the same word line WL.

In step S320, a predetermined voltage is applied to the word line corresponding to the first and second cell regions so as to turn on the first and second transistors.

Reference is made to FIG. 12. The same reference voltage is applied to all of the common-source lines SL, and the reference voltage is about ⅓ of the threshold voltage (Vpp) of the FTJ unit. Furthermore, the adjacent first and second cell regions R1 and R2 corresponding to the same word line WL(1) are defined as a bit zone B. Accordingly, the first transistor T1 and the second transistor T2 are turned on by applying the predetermined voltage to the word line WL(1) during writing.

Reference is made to FIG. 11A. In step S330, a first operation voltage is applied to the first bit line corresponding to the first cell region so as to create a first voltage difference between the first operation voltage and the reference voltage, and a second operation voltage is applied to the second bit line corresponding to the second FTJ unit so as to create a second voltage difference between the second operation voltage and the reference voltage.

As shown in FIG. 12, a first operation voltage is applied to the bit line BL(5) corresponding to the first cell region R1. In the present embodiment, the first operation voltage is 4/3 of the threshold voltage (Vpp) of the first FTJ unit F1 during programming the first FTJ unit F1 in the first cell region R1. Therefore, the first voltage difference between the first operation voltage (4/3Vpp) and the reference voltage (⅓Vpp) is exactly equal to the threshold voltage (Vpp) of the first FTJ unit F1, so that the polarization direction and resistance of the ferroelectric film of the first FTJ unit F1 are changed.

Similarly, a second operation voltage is applied to another bit line BL(6) corresponding to the second cell region R2. In the present embodiment, the second operation voltage is −⅔ of the threshold voltage (Vpp) of the second FTJ unit during the programming of the second FTJ unit F2. Therefore, an absolute value of the second voltage difference (−Vpp) between the second operation voltage (−⅔Vpp) and the reference voltage (⅓Vpp) is also equal to the threshold voltage (Vpp) of the second FTJ unit F2. However, the polarization direction of the ferroelectric film of the second FTJ unit F2 is opposite to that of the ferroelectric film of the first FTJ unit F1.

However, in another embodiment of the present disclosure, the second operation voltage may also be equal to the first operation voltage, such that the ferroelectric film of the second FTJ unit F2 and the ferroelectric film of the first FTJ unit F1 are polarized in the same direction.

Furthermore, as shown in FIG. 12, the operation voltage applied to the other bit lines (such as the bit line BL(4)) respectively corresponding to the other un-selected cell regions is ⅓ of the threshold voltage. Accordingly, the voltage difference between the operation voltage (⅓Vpp) and the reference voltage (⅓Vpp) is equal to zero, such that the FTJ unit in the cell region corresponding to the bit line BL(4) is in the unwritten state.

Reference is made to FIG. 11B, in step S340, whether the first FTJ unit is in a written state or an unwritten state is determined according to the first voltage difference and the threshold voltage of the first FTJ unit, and whether the second FTJ unit is in a written state or an unwritten state is determined according to the second voltage difference and the threshold voltage of the second FTJ unit.

To be more specific, in the present embodiment, the step S340 further includes steps S341-S343. In step S341, it is determined whether both of the first voltage difference and the second voltage difference are either greater than or equal to the threshold voltage. When both the first voltage difference and the second voltage difference are less than the threshold voltage, the method proceeds to step S342, in which the first FTJ unit and the second FTJ unit are both determined to be in the unwritten state. When both of the first voltage difference and the second voltage difference are either greater than or equal to the threshold voltage, the method proceeds to step S343, in which the first FTJ unit and the second FTJ unit are both determined to be in the written state.

When each of the first FTJ unit and the second FTJ unit is determined to be in the written state, the method proceeds to step S350. In step S350, it is determined whether the bit zone is in a first bit state or a second bit state according to the written states of the first and second FTJ units.

The step S350 further includes steps S351-S355. In step S351, the read voltage is applied to each of the first and second bit lines to measure the first current and second current.

As shown in FIG. 13, when determining the written states of the first and second FTJ units F1, F2, the read voltage Vd is applied to each of the bit line BL(5) corresponding to the first cell region R1 and the bit line BL(6) corresponding to the second cell region R2 so as to measure the first current through the first FTJ unit F1 and the second current through the second FTJ unit F2. In the present embodiment, a ratio of the read voltage Vd to the threshold voltage ranges between 0.4 and 0.8.

Reference is made to FIG. 11B. In one embodiment, after the step S351 is performed, the method proceeds to step S352. In step S352, it is determined whether both of the first current and the second current are either greater than or less than a reference current, or whether one of the first current and the second current is greater than the reference current, while the other is less than the reference current. When both of the first current and the second current are greater than or less than a reference current, the method proceeds to step S354, in which the bit zone is determined to be in the first bit state. When one of the first current and the second current is greater than the reference current, while the other is less than the reference current, the method proceeds to step S355, in which the bit zone is determined to be in the second bit state.

Specifically, when both the first current and the second current are greater than the reference current, the first FTJ unit and the second FTJ unit are both in the first state with low resistance, which is, for example, defined as “1”. When both the first current and second current are less than the reference current, the first FTJ unit and the second FTJ unit are both in the second state with high resistance, which is, for example, defined as “0”.

That is to say, when both the first FTJ unit and second FTJ unit are in either the first state or in the second state, the bit zone is determined to be in the first bit state.

Furthermore, when the written states of the first and second FTJ units are respectively in the first state and the second state, the bit zone is determined to be in the second bit state. In one embodiment, the first bit state is defined as “1”, and the second bit state is defined as “0”.

Referring to the following Table 1, the relations between the written state of the bit zone and the written states of the first and second FTJ units according to the present embodiment are listed.

TABLE 1

| written state of the | written state of the | written state of the |
|---|---|---|
| first FTJ unit | second FTJ unit | bit zone |
| first state, defined | first state, defined | first bit state, defined |
| as “1” | as “1” | as “1” |
| second state, defined | second state, defined | first bit state, defined |
| as “0” | as “0” | as “1” |
| first state, defined | second state, defined | second bit state, defined |
| as “1” | as “0” | as “0” |
| second state, defined | first state, defined | second bit state, defined |
| as “0” | as “1” | as “0” |

In another embodiment, after the step S351, the method proceeds to step S353. In step S353, it is determined whether the first current is greater than the reference current and whether the second current is less than the reference current. If yes, that is, when the first current is greater than the reference current, and the second current is less than the reference current, the method proceeds to step S354, in which the bit zone is determined to be in the first bit state. In other words, when the written state of the first FTJ unit is the first state, and the written state of the second FTJ unit is the second state, the bit zone is determined to be in the first bit state.

However, when either the first current is less than the reference current or the second current is greater than the reference current, the method proceeds to step S355, in which the bit zone is determined to be in the second bit state. That is to say, when either the written state of the first FTJ unit is the second state or the written state of the second FTJ unit is the first state, the bit zone is determined to be in the second bit state. Referring to the following Table 2, the relations between the written state of the bit zone and the written states of the first and second FTJ units according to the present embodiment are listed.

TABLE 2

| written state of the | written state of the | written state of the |
|---|---|---|
| first FTJ unit | second FTJ unit | bit zone |
| first state, defined | second state, defined | first bit state, defined |
| as “1” | as “0” | as “1” |
| second state, defined | first state, defined | second bit state, defined |
| as “0” | as “1” | as “0” |
| second state, defined | second state, defined | second bit state, defined |
| as “0” | as “0” | as “0” |
| first state, defined | first state, defined | second bit state, defined |
| as “1” | as “1” | as “0” |

In summary, in the present disclosure, by varying the type and the doping concentration of dopants in the base substance of the ferroelectric film, the coercive electric field of the ferroelectric film can be tuned to expand the range of application of the FTJ unit. Furthermore, the fabrication processes of the FTJ unit can be integrated into current semiconductor processes, which benefits mass production.

Furthermore, the FTJ unit can be applied in the memory element. Since the read voltage of the memory element during operation positively correlates to the coercive electric field of the ferroelectric film, by utilizing the dopants of higher conductivity (such as titanium nitride or tantalum nitride) in the ferroelectric film to reduce the coercive electric field, the read voltage of the memory element can be decreased, thus reducing the power consumption of the memory element.

The present disclosure further provides the method of writing and reading the memory element. During programming or reading one of the FTJ elements arranged in a selected cell region, the reference voltage applied to each of the common-source lines, and the operation voltage and read voltage applied to each of the bit lines are controlled to prevent the written state of another FTJ unit in the un-selected cell region that is adjacent to the selected cell region from being disturbed.

Furthermore, by defining two adjacent cell regions as a bit zone, and determining the written states of the first and second FTJ units respectively arranged in two adjacent cell regions, the errors or difficulty in determination due to large differences in characteristics between the FTJ units may be reduced, thus increasing the accuracy of determination.

The aforementioned descriptions merely represent the preferred embodiments of the present disclosure, without any intention to limit the scope of the present disclosure which is fully described only within the following claims. Various equivalent changes, alterations or modifications based on the claims of the present disclosure are all, consequently, viewed as being embraced by the scope of the present disclosure.

What is claimed is:

1. A ferroelectric tunnel junction unit, comprising:
a first electrode;
a second electrode; and
a ferroelectric film sandwiched between the first electrode and the second electrode;
wherein the ferroelectric film includes at least a base substance and a number of dopants, the base substance including two oxides, each oxide being at least one of an alkaline-earth metal oxide and a transition metal oxide, and the dopants including aluminum, silicon, titanium, tantalum, nitrogen, lanthanum, tantalum nitride, titanium nitride, or any combination thereof.

2. The ferroelectric tunnel junction unit according to claim 1, wherein the base substance includes hafnium oxide and zirconium oxide.

3. The ferroelectric tunnel junction unit according to claim 2, wherein a general formula of the base substance is HfxZr(1-x)Oy, x ranges between 0.25 and 0.75, and y ranges between 1.8 and 2.2.

4. The ferroelectric tunnel junction unit according to claim 3, wherein the dopants include silicon oxide, aluminum oxide, or a combination of silicon oxide and aluminum oxide, and a doping concentration of the dopants ranges between 1% and 5%.

5. The ferroelectric tunnel junction unit according to claim 2, wherein the dopants includes titanium nitride or tantalum nitride, and a doping concentration of the dopants ranges between 1% and 10%.

6. The ferroelectric tunnel junction unit according to claim 2, wherein a general formula of the base substance is HfₓZr_{(1-1.25x)}O_{y}, x ranges between 0.2 and 0.6, y ranges between 1.8 and 2.2, the dopants include silicon, and a ratio of a number of hafnium atoms to a number of silicon atoms ranges between 4 and 9.

7. The ferroelectric tunnel junction unit according to claim 1, wherein the materials of the first electrode and the second electrode are selected from a group consisting of titanium nitride, tantalum nitride and heavily-doped semiconductor.

8. A manufacturing method of a ferroelectric film, comprising:
forming a laminate body including a first base substance stack structure and at least one dopant material structure, wherein the first base substance stack structure includes at least one oxide, the oxide being at least one of an alkaline-earth metal oxide and a transition metal oxide, the dopant material structure includes a number of dopants, the dopants including aluminum, silicon, titanium, tantalum, nitrogen, lanthanum, tantalum nitride, titanium nitride, or any combination thereof; and
performing a heating process on the laminate body so that atoms in the first base substance stack structure interdiffuse with the dopants in the dopant material structure to form the ferroelectric film.

9. The manufacturing method according to claim 8, wherein the dopants include silicon oxide, aluminum oxide, titanium nitride, tantalum nitride or any combination thereof.

10. The manufacturing method according to claim 9, wherein the first base substance stack structure includes a first oxide layer and a second oxide layer directly connected to the first oxide layer, the first oxide layer and the second oxide layer respectively include an oxide, and each of the oxides is at least one of the alkaline earth metal oxide and the transition metal oxide.

11. The manufacturing method according to claim 9, wherein the first base substance stack structure includes two first oxide layers connected to each other.

12. The manufacturing method according to claim 11, wherein the laminate body further includes a second base substance stack structure, and the dopant material structure is sandwiched between the first base substance stack structure and the second base substance stack structure.

13. The manufacturing method according to claim 12, wherein the second base substance stack structure includes two second oxide layers connected to each other, each of the first oxide layers and each of the second oxide layers respectively include an oxide, and each oxide is at least one of the alkaline earth metal oxide and the transition metal oxide.

14. The manufacturing method according to claim 8, wherein the dopants include silicon, the dopant material structure further includes the transition metal oxide, and a ratio of a number of transition metal atoms in the dopant material structure to a number of silicon atoms in the dopant material structure ranges between 4 and 9.

15. The manufacturing method according to claim 14, wherein the first base substance stack structure includes two first oxide layers connected to each other.

16. A memory element comprising:
a plurality of bit lines extending along a first direction;
a plurality of common-source lines extending along the first direction, wherein the common-source lines and the bit lines are alternately arranged;
a plurality of word lines extending along a second direction, wherein the word lines respectively intersect with the common-source lines and the bit lines to define a plurality of cell regions;
a plurality of transistors respectively arranged in the cell regions, wherein each of the transistors includes a source electrode, a drain electrode and a gate electrode, the drain electrode is electrically connected to the corresponding bit line, and the gate electrode is electrically connected to the corresponding word line; and
a plurality of ferroelectric tunnel junction units respectively arranged in the cell regions, wherein the ferroelectric tunnel junction units are respectively electrically connected to the transistors, and each of the ferroelectric tunnel junction units includes:
a first electrode electrically connected to the source electrode;
a second electrode electrically connected to the corresponding common-source line; and
a ferroelectric film sandwiched between the first electrode and the second electrode, wherein the ferroelectric film includes a base substance and a number of dopants, the base substance including two oxides, each oxide being at least one of an alkaline-earth metal oxide and a transition metal oxide, and the dopants including aluminum, silicon, titanium, tantalum, nitrogen, lanthanum, tantalum nitride, titanium nitride, or any combinations thereof.

17. A method of writing and reading the memory element according to claim 16 comprising:
applying a reference voltage to each of the common-source lines;
selecting a first cell region from the cell regions, wherein a first transistor and a first ferroelectric tunnel junction unit electrically connected to each other are arranged in the first cell region;
applying a predetermined voltage to the corresponding word line of the first cell region so as to turn on the first transistor;
applying a first operation voltage to a corresponding first bit line of the first cell region so as to create a first voltage difference between the first operation voltage and the reference voltage; and
determining whether the first ferroelectric tunnel junction unit is in a written state or in an unwritten state according to the first voltage difference and a threshold voltage of the first ferroelectric tunnel junction unit.

18. The method according to claim 17, wherein the step of determining whether the first ferroelectric tunnel junction unit is in the written state or in the unwritten state further includes:
determining the first ferroelectric tunnel junction unit to be in the written state when the first voltage difference is greater than or equal to the threshold voltage; and
determining the first ferroelectric tunnel junction unit to be in the unwritten state when the first voltage difference is less than the threshold voltage.

19. The method according to claim 18, wherein the step of determining the first ferroelectric tunnel junction unit to be in the written state further includes:
applying a read voltage to the first bit line to measure a first current;
comparing the first current with a reference current to determine whether the written state of the first ferroelectric tunnel junction unit is a first state with low resistance or a second state with high resistance;
determining the written state of the first ferroelectric tunnel junction unit to be the first state with low resistance when the reference current is less than the first current; and
determining the written state of the first ferroelectric tunnel junction unit to be the second state with high resistance when the reference current is greater than the first current.

20. The method according to claim 19, wherein a ratio of the read voltage to the threshold voltage ranges between 0.4 and 0.8.

21. The method according to claim 18 further comprising:
selecting a second cell region adjacent to the first cell region, wherein a second transistor and a second ferroelectric tunnel junction unit electrically connected to the second transistor are arranged in the second cell region, and the first transistor and the second transistor are both electrically connected to the same word line;
applying a second operation voltage to a second bit line corresponding to the second ferroelectric tunnel junction unit so as to create a second voltage difference between the second operation voltage and the reference voltage; and
determining whether the second ferroelectric tunnel junction unit is in a written state or in an unwritten state according to the second voltage difference and a threshold voltage of the second ferroelectric tunnel junction unit.

22. The method according to claim 21, wherein the step of determining whether the second ferroelectric tunnel junction unit is in the written state or in the unwritten state further includes:
determining the second ferroelectric tunnel junction unit to be in the written state when the second voltage difference is greater than or equal to the threshold voltage of the second ferroelectric tunnel junction unit; and
determining the second ferroelectric tunnel junction unit to be in the unwritten state when the second voltage difference is less than the threshold voltage of the second ferroelectric tunnel junction unit.

23. The method according to claim 22, wherein the step of determining the second ferroelectric tunnel junction unit to be in the written state further includes:
applying a read voltage to the second bit line to measure a second current;
comparing the second current with the reference current to determine whether the written state of the second ferroelectric tunnel junction unit is a first state with low resistance or a second state with high resistance;
determining the written state of the second ferroelectric tunnel junction unit to be the first state with the low resistance when the reference current is less than the second current; and
determining the written state of the second ferroelectric tunnel junction unit to be the second state with high resistance when the reference current is greater than the second current.

24. The method according to claim 23, further comprising:
selecting and defining the first cell region and the adjacent second cell region as a bit zone; and
determining whether the bit zone is in a first bit state or a second bit state according to the written states of the first ferroelectric tunnel junction unit and the second ferroelectric tunnel junction unit.

25. The method according to claim 24, wherein the step of determining whether the bit zone is in the first bit state or the second bit state further includes:
determining the bit zone to be in the first bit state when both the written states of the first ferroelectric tunnel junction unit and the second ferroelectric tunnel junction unit are in either the first state or the second state; and
determining the bit zone to be in the second bit state when the written states of the first ferroelectric tunnel junction unit and the second ferroelectric tunnel junction unit are different from each other.

26. The method according to claim 24, wherein the step of determining whether the bit zone is in the first bit state or the second bit state further includes:
determining the bit zone to be in the first bit state when the written state of the first ferroelectric tunnel junction unit is the first state, and the written state of the second ferroelectric tunnel junction unit is the second state; and
determining the bit zone to be in the second bit state when either the written state of the first ferroelectric tunnel junction unit is the second state or the written state of the second ferroelectric tunnel junction unit is the first state.

27. The method according to claim 17, wherein the reference voltage is ⅓ of the threshold voltage, and the first operation voltage is 4/3 or −⅔ of the threshold voltage so that the first ferroelectric tunnel junction unit is in the written state.

28. The method according to claim 27, wherein the first operation voltage is −⅔ of the threshold voltage so that the written state of the first ferroelectric tunnel junction unit is a first state with low resistance.

29. The method according to claim 27, wherein the first operation voltage is 4/3 of the threshold voltage so that the written state of the first ferroelectric tunnel junction unit is a second state with high resistance.

30. The method according to claim 17, wherein the reference voltage and the first operation voltage are both ⅓ of the threshold voltage so that the first ferroelectric tunnel junction unit is in the unwritten state.
